(19) United States
(12) Patent Application Publication
(10) Pub. No.: US 2012/0091861 A1
(43) Pub. Date: Apr. 19, 2012

(54) CERAMIC COMPOSITION FOR PIEZOELECTRIC ACTUATOR AND PIEZOELECTRIC ACTUATOR COMPRISING THE SAME

(75) Inventors: Boum Seock KIM, Gyunggi-do (KR); Eun Tae Park, Gyunggi-do (KR); Seung Gyo Jeong, Gyunggi-do (KR); Sahn Nahm, Seoul (KR); Chan Hee Nam, Daejeon (KR)

(73) Assignees: KOREAN UNIVERSITY INDUSTRIAL & ACADEMIC COLLABORATION FOUNDATION; SAMSUNG ELECTRO-MECHANICS CO., LTD.

(21) Appl. No.: 13/075,970

(22) Filed: Mar. 30, 2011

(30) Foreign Application Priority Data
Oct. 13, 2010 (KR) 10-2010-0100025

(51) Int. Cl. H01L 41/187; H01L 41/24

(52) U.S. Cl. 310/363; 252/62.9 PZ; 29/25.35

(57) ABSTRACT

The present invention relates to a ceramic composition for a piezoelectric actuator and a piezoelectric actuator comprising the same. The ceramic composition for piezoelectric actuator includes a piezoelectric ceramic powder expressed by a Chemical Formula: (1-x)Pb(Zr_{(1-y)}Ti_{y})O₃-xPb(Ni_{1/3}Nb_{2/3})O₃, wherein x is 0.25 to 0.4 and y is 0.4 to 0.7; and a CuO powder and a PbO powder forming a liquid-phase compound at a sintering temperature or less of the piezoelectric ceramic powder. The ceramic composition for a piezoelectric actuator according to the present invention exhibits excellent piezoelectric characteristics and allows for low-temperature firing.

### CROSS-REFERENCE TO RELATED APPLICATIONS

This application claims the priority of Korean Patent Application No. 10-2010-0100025 filed on Oct. 13, 2010, in the Korean Intellectual Property Office, the disclosure of which is incorporated herein by reference.

### BACKGROUND OF THE INVENTION

1. Field of the Invention

The present invention relates to a ceramic composition for a piezoelectric actuator and a piezoelectric actuator comprising the same, and more particularly, to a ceramic composition capable of being fired at a low temperature while having excellent piezoelectric characteristics and a piezoelectric actuator comprising the same.

2. Description of the Related Art

Recently, with the development of the precision machinery industry and the information industry, a piezoelectric actuator controlling minute displacements or vibrations has been prevalently used in precision optical instruments, semiconductor equipment, pumps for controlling gas flow rates, valves, and the like. As compared to existing mechanical driving devices, the piezoelectric actuator can be manufactured to have a small size, have precision control, and have a rapid response rate.

Therefore, with the development of mechatronics, components for controlling minute displacements tend to use a piezoelectric actuator rather than to use the existing step motor. As a result, there is a need for a material generating a high level of displacement when the piezoelectric actuator using a piezoelectric ceramic is applied.

The currently used actuator has mainly used PZT(Pb(ZrTi)O3), a relaxor ferroelectric materials including Pb, or the like. These materials are not actually used since the displacement of a specimen is below 1% in disk.

To solve this problem, various types of actuators such as a cantilever type actuator, a flextensional type actuator, and a multi-layered actuator have been developed.

Since a disk-type PZT is deformed at high voltage, in the multi-layered actuator each layer is thinned in order to lower a use voltage and generate a high electric field, even at low voltage, by inserting parallel electrodes into each disk. In the case of the multi-layered actuator, there are a method of cutting and bonding a simple multi-layer actuator and a simultaneous sintering method of tape-casting and printing.

The cutting and bonding method is a method of bonding a thinly manufactured piezoelectric PZT to a copper foil using a silver epoxy. In this case, since the piezoelectric material is machined to a thickness of 0.3 mm to 1 mm and bonded, it is easily manufactured, but requires a relatively high operational voltage.

The tape-casting and printing methods are methods of mixing the PZT with a polymer, extracting the mixture in a thin tape form, printing an electrode material such as Pd, or the like, thereon, bonding several layers, burning the polymer, and simultaneously sintering it. In this case, since a process of manufacturing a tape-casted ceramic-polymer composite in a thin tape form is complicated and a print process is hard to perform, manufacturing costs may be increased, but a layer may be manufactured to be very thin.

Meanwhile, when the sintering is performed at a high temperature (about 1200° C.) by applying a high temperature co-firing ceramic (HTCC) process, expensive rare metals (Pt, Pd, or the like) can generally be used. As metals that can endure relatively high temperatures and have good conductivity, rare metals such as Pt, Pd, or the like, are used.

Therefore, in the case that relatively inexpensive metals such as silver, copper, aluminum, or the like, can be used for electrodes by lowering a sintering temperature, it is possible to considerably lower manufacturing costs.

### SUMMARY OF THE INVENTION

An aspect of the present invention provides a ceramic composition capable of being fired at a low temperature while having excellent piezoelectric characteristics and a piezoelectric actuator comprising the same.

According to an aspect of the present invention, there is provided a ceramic composition for a piezoelectric actuator, comprising: a piezoelectric ceramic powder expressed by a Chemical Formula: (1-x)Pb(Zr(_{1-y})Ti_{y})O₃-xPb(Ni_{1/3}Nb_{2/3})O₃, wherein x is 0.25 to 0.4 and y is 0.4 to 0.7; and a CuO powder and a PbO powder forming a liquid-phase compound at a sintering temperature or less of the piezoelectric ceramic powder.

The CuO powder and the PbO powder may be included in amounts of 10 mol % or less.

The ceramic composition for a piezoelectric actuator may further include a ZnO powder in an amount of 10 mol % or less.

According to another aspect of the present invention, there is provided a method for manufacturing a ceramic composition for a piezoelectric actuator, comprising: manufacturing a piezoelectric ceramic powder expressed by a Chemical Formula: (1-x)Pb(Zr_{(1-y)}Ti_{y})O₃-xPb(Ni_{1/3}Nb_{2/3})O₃ by mixing and calcinating a powder material, wherein x is 0.25 to 0.4 and y is 0.4 to 0.7; and mixing the piezoelectric ceramic powder with a CuO powder and a PbO powder.

The powder material may be PbO, ZrO, TiO₂, NiO, and Nb₂O₅.

The CuO powder and the PbO powder may be mixed in amounts of 10 mol % or less.

The mixing may further mix ZnO at 10 mol % or less.

According to another aspect of the present invention, there is provided a piezoelectric actuator, comprising: at least one piezoelectric layer comprising a ceramic composition including a piezoelectric ceramic powder expressed by a Chemical Formula: (1-x)Pb(Zr_{(1-y)}Ti_{y})O₃-xPb(Ni_{1/3}Nb_{2/3})O₃, wherein x is 0.25 to 0.4 and y is 0.4 to 0.7, and a CuO powder and a PbO powder forming a liquid-phase compound at a sintering temperature or less of the piezoelectric ceramic powder; and an electrode layer formed on at least one of the top surface and the bottom surface of the piezoelectric layer.

The piezoelectric layer may further include ZnO in an amount of 10 mol % or less.

The electrode layer may include at least one selected from the group consisting of silver, copper, and aluminum.

According to another aspect of the present invention, there is provided a method for manufacturing a piezoelectric actuator, comprising: manufacturing a piezoelectric ceramic powder expressed by a Chemical Formula: (1-x)Pb(Zr_{(1-y)}Ti_{y})O₃-xPb(Ni_{1/3}Nb_{2/3})O₃ by mixing and calcinating a powder material, wherein x is 0.25 to 0.4 and y is 0.4 to 0.7; and manufacturing a ceramic composition by mixing the piezoelectric ceramic powder with a CuO powder and a PbO powder forming a liquid-phase compound at a sintering temperature or less of the piezoelectric ceramic powder; forming a piezoelectric layer using the ceramic composition; forming a laminate by forming an electrode layer on at least one of the top surface and the bottom surface of the piezoelectric layer; and firing the laminate at 950° C. or less.

The powder material may be PbO, ZrO, TiO₂, NiO, and Nb₂O₅.

The CuO powder and the PbO powder may be mixed in amounts of 10 mol % or less.

The manufacturing of the ceramic composition may further mix a ZnO powder in an amount of 10 mol % or less.

The electrode layer may include at least one selected from a group consisting of silver, copper, and aluminum.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view schematically showing a piezoelectric actuator according to an exemplary embodiment of the present invention; and

FIG. 2 is a graph showing piezoelectric characteristics of a sample manufactured according to the exemplary embodiment of the present invention.

### DETAILED DESCRIPTION OF THE PREFERRED EMBODIMENT

Exemplary embodiments of the present invention will now be described in detail with reference to the accompanying drawings.

A ceramic composition for a piezoelectric actuator according to an exemplary embodiment of the present invention includes a PZT-PNN piezoelectric ceramic powder.

In more detail, the PZT-PNN piezoelectric ceramic powder is represented by a Chemical Formula: (1-x)Pb(Zr_{(1-y)}Ti_{y})O₃-xPb(Ni_{1/3}Nb_{2/3})O₃, wherein x is 0.25 to 0.4 and y is 0.4 to 0.7.

The piezoelectric ceramic powder according to the exemplary embodiment of the present invention is obtained by adding Pb(Ni_{1/3}Nb_{2/3})O₃ to Pb(ZrTi)O₃. The piezoelectric characteristics of PZT are improved by adding a small amount of PNN to PZT.

Herein, x, which is the addition of the PNN, may be 0.25 to 0.4. When an excessive amount of the PNN is added, the piezoelectric characteristics may be lost.

In the case of PZT, y, which is a ratio of Zr to Ti, may be 0.4 to 0.7. The PZT-PNN piezoelectric ceramic powder may exhibit excellent piezoelectric characteristics by controlling the ratio of Zr to Ti.

The ceramic composition for a piezoelectric actuator according to the exemplary embodiment of the present invention includes a CuO powder and a PbO powder.

The CuO powder and the PbO powder react with each other to form a liquid-phase compound at a sintering temperature of the PZT-PNN piezoelectric ceramic powder or less. The liquid-phase compound promotes the sintering of the PZT-PNN piezoelectric ceramic powder to lower the sintering temperature of the ceramic composition.

The content of the CuO powder and the PbO powder may be in amounts of 10 mol % or less, more specifically, the CuO powder and the PbO powder may be each included in amounts of 5 mol %.

In addition, the ceramic composition for a piezoelectric actuator according to the exemplary embodiment of the present invention may additionally include a ZnO powder and the content of the ZnO powder may be 10 mol % or less.

When the ZnO powder is additionally included, the piezoelectric characteristics for the ceramic composition for a piezoelectric actuator may be improved.

The PZT-PNN piezoelectric ceramic powder according to the exemplary embodiment of the present invention may be manufactured by mixing a powder material and calcinating it.

The present invention is not limited thereto, but the powder material may be PbO, ZrO₂, TiO₂, NiO, and Nb₂O₅.

The content of each powder material has a composition of (1-x)Pb(Zr_{(1-y)}Ti_{y})O₃-xPb(Ni_{1/3}Nb_{2/3})O₃ after the calcination, wherein x is 0.25 to 0.4 and y is 0.4 to 0.7.

The PZT-PNN, which is a Perovskite powder having a stable ABO₃ structure, may be manufactured during the mixing and calcination of the powder material.

The calcination may be performed at 800 to 1000° C. for 2 to 5 hours.

The ceramic composition for a piezoelectric actuator maybe manufactured by mixing the PZT-PNN piezoelectric ceramic powder and the CuO powder and the PbO powder.

The CuO powder and the PbO powder may be added at 10 mol % or less and may be mixed with the piezoelectric ceramic powder, i.e., the PZT-PNN by a milling process, or the like, thereby completing the ceramic composition for a piezoelectric actuator.

Further, the ZnO powder in an amount of 10 mol % or less may be further added to the ceramic composition for a piezoelectric actuator according to the exemplary embodiment of the present invention.

Generally, in order to implement the multi-layered piezoelectric actuator, the electrode and the piezoelectric material are configured as a multi-layered type. Therefore, the interface form between the electrode and the piezoelectric material is stably maintained and the simultaneous firing between the electrode and the piezoelectric material should be performed during the process.

The melting point of the electrode needs to be higher than the firing temperature in order to perform the simultaneous firing.

As the piezoelectric material used for the existing multi-layered piezoelectric actuator, the PZT-based material is mainly used. In this case, the firing temperature is a very high temperature of 1100 to 1250° C. Therefore, the electrode material capable of maintaining characteristics at the firing temperature should be used between the multi-layered PZT piezoelectric layers.

Therefore, the electrode material mainly including Pd, an expensive electrode material, has been used.

As the usage of Pd is increased, the price of the piezoelectric actuator is remarkably increased. Therefore, research into lowering firing temperatures while maintaining the piezoelectric characteristics, by adding a new composition to the PZT-based material, has been conducted.

When the firing temperature of the piezoelectric material is lowered, the low-temperature electrode material including a low content Pd may be used, such that the manufacturing costs can be greatly lowered.

The ceramic composition for a piezoelectric actuator according to the exemplary embodiment of the present invention can be sintered at a low temperature of 950° C. Therefore, the low-temperature electrode material including a low content Pd may be used.

Another exemplary embodiment of the present invention relates to a piezoelectric actuator comprising the ceramic composition for a piezoelectric actuator.

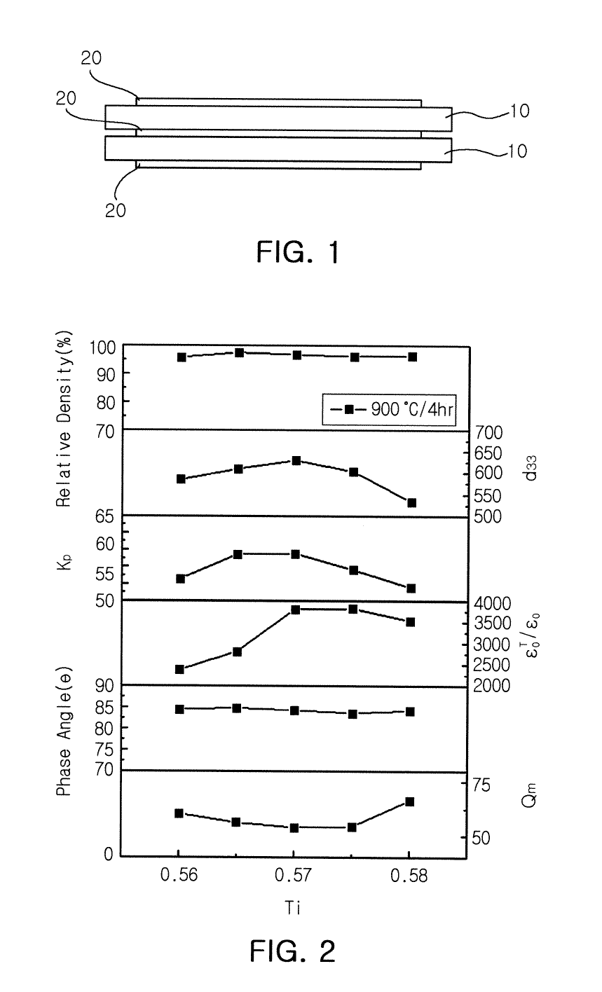

FIG. 1 is a cross-sectional view schematically showing a piezoelectric actuator according to an exemplary embodiment of the present invention.

Referring to FIG. 1, the piezoelectric actuator according to the exemplary embodiment of the present invention may be configured to include a piezoelectric layer 10 and an electrode layer 20 formed on at least one of the top surface and the bottom surface of the piezoelectric layer.

The piezoelectric layer 10 may be configured as a multilayer of at least one layer and include the ceramic composition for a piezoelectric actuator according to the exemplary embodiment of the present invention.

As described above, the ceramic composition for a piezoelectric actuator according to the exemplary embodiment of the present invention has the piezoelectric ceramic powder having a composition of (1-x)Pb(Zr_{(1-y)}Ti_{y})O₃-xPb(Ni_{1/3}Nb_{2/3})O₃ and includes in which x is 0.25 to 0.4 and y is 0.4 to 0.7, and the CuO powder and the PbO powder forming the liquid-phase compound at the sintering temperature or less of the piezoelectric ceramic powder.

In addition, the ceramic composition for a piezoelectric actuator may further include ZnO in an amount of 10 mol % or less.

The piezoelectric layer 10 can be fired at a low temperature and the electrode layer 20 may use Pd and a low-temperature electrode material comprising low content Pd.

The low-temperature electrode material means an electrode material that cannot be applied to the high-temperature simultaneous firing by exhibiting the unsuitable characteristics for an electrode material in the sintering body, i.e., the conductive characteristics, or by degrading the entire characteristics of the sintered body, when simultaneously fired at a high temperature together with the piezoelectric material. The exemplary embodiment of present invention may use the low-temperature electrode material but is not limited thereto. For example, the exemplary embodiment of the present invention may use metals such as silver, copper, aluminum, or the like, and may include an electrode layer of silver.

Alternatively, the exemplary embodiment of the present invention may use the low-temperature electrode material and an alloy of Pd, wherein the content of Pd may be 10% or less in the alloy.

The piezoelectric actuator according to the exemplary embodiment of the present invention may be manufactured by manufacturing the piezoelectric layer by using the above-mentioned ceramic composition for a piezoelectric actuator, forming the electrode layer on at least one of the top surface and the bottom surface of the piezoelectric layer to prepare a laminate, and simultaneously firing it at a low temperature.

The simultaneous firing temperature may be 950° C. or less, preferably, 900° C.

The simultaneous firing may be performed at 950° C. or less and thus the low-temperature electrode material may be used. Even when the low-temperature electrode material is used, the conductive characteristics of the electrode layer and the piezoelectric characteristics of the sintered body are not degraded.

Hereinafter, the exemplary embodiment of the present invention will be described in more detail but the scope of the present invention is not to be construed as being limited to the following exemplary embodiment.

The powder material of PbO, ZrO₂, TiO₂, NiO, and Nb₂O₅ was weighed to have the following composition and a ball-milling process was performed for 12 hours using a solvent (ethanol or distilled water). In this case, ZrO₂ and TiO₂ were weighed to have a composition as described in the following Table 1.

Thereafter, they were subjected to a drying process, were contained in a furnace, and were subjected to the calcination heat treatment at 850° C. for 4 hours, thereby synthesizing the PZT-PNN composition.

The PbO, CuO, and ZnO powders were added and mixed to the completed PZT-PNN piezoelectric ceramic powder to have the ratio below. In the present experimental embodiment, the wetting ball-milling process was performed for 24 hours as the mixing process.

0.65[Pb(Zr_{(1-y)}Ti_{y})O₃]−0.35[Pb(Ni_{1/3}Nb_{2/3})O₃]+3 mol % ZnO+1 mol % CuO+1 mol % PbO

Thereafter, the powder obtained through the drying was compressed and molded and subjected to the sintering heat treatment, thereby manufacturing the sample. The sintering was performed at 900 to 950° C. for 2 hours. The completed sample size was a disk having a diameter of 12.5 mm and a thickness of 0.88 mm, the electrode was coated on the top surface and the bottom surface thereof, and polling was performed thereon at a voltage of 4 kV/mm.

The piezoelectric characteristics of the manufactured sample were measured, which is shown in the following Table 1 and FIG. 2.

As the equipment used for measuring characteristics, a d₃₃ meter (Micro-Epsilon Channel Product DT-3300, Raleigh, N.C.) and an impedance analyzer (Agilent Technologies HP 4294A, Santa Clara, Calif.) were used.

TABLE 1

| y | Relative | | | | |
|---|---|---|---|---|---|
| (Ti | Density | | | Dielectric | |
| ratio) | (%) | d33(pC/N) | kp | Constant | Qm |
| 0.560 | 95.0 | 570 | 62.5 | 2480 | 59.5 |
| 0.565 | 97.8 | 605 | 65.3 | 2724 | 57.6 |
| 0.570 | 96.9 | 630 | 65.5 | 3760 | 55.4 |
| 0.575 | 96.0 | 600 | 63.5 | 3778 | 56.2 |
| 0.580 | 96.2 | 530 | 61.9 | 3520 | 63.2 |

The easiest method of confirming whether the firing of the piezoelectric material was completely made is a method of measuring density after the firing. Generally, the PZT-based material is able to obtain a desired sintering density in the vicinity of 1000° C.

However, as shown in the above Table 1 and FIG. 2, it could be confirmed that the ceramic composition for a piezoelectric actuator according to the exemplary embodiment of the present invention exhibits excellent piezoelectric characteristics and performance according to the firing results at 900 to 950° C.

That is, according to the exemplary embodiment of the present invention, it could be confirmed that the ceramic composition for a piezoelectric actuator could be fired at a low temperature of 950° C. or less and the piezoelectric material having excellent characteristics reaching a piezoelectric constant value of 600 and a mechanical coupling coefficient of 65% could be manufactured.

When the piezoelectric material having the low firing temperature is actually used for the piezoelectric component, it is possible to implement these characteristics through only Pd of 10% or less or 100% Ag not having Pd as the internal electrode.

As set forth above, according to exemplary embodiments of the present invention, a ceramic composition for a piezoelectric actuator that can be fired at a low temperature can be provided by using a PZT-PNN ceramic powder, a CuO powder, and a PbO powder having specific composition.

The piezoelectric actuator can be manufactured by using the ceramic composition for a piezoelectric actuator using the low-cost electrode material.

Therefore, the manufacturing costs of the piezoelectric actuator can be remarkably lowered and the piezoelectric actuator can have the excellent piezoelectric characteristic values even in the low-temperature firing and be applied to various products.

While the present invention has been shown and described in connection with the exemplary embodiements, it will be apparent to those skilled in the art that modification and variation can be made withough departing from the spirit and scope of the invention as defined by the appended claims.

What is claimed is:

1. A ceramic composition for a piezoelectric actuator, comprising:
a piezoelectric ceramic powder expressed by a Chemical Formula: (1-x)Pb(Zr_{(1-y)}Ti_{y})O₃-xPb(Ni_{1/3}Nb_{2/3})O₃, wherein x is 0.25 to 0.4 and y is 0.4 to 0.7; and
a CuO powder and a PbO powder forming a liquid-phase compound at a sintering temperature or less of the piezoelectric ceramic powder.

2. The ceramic composition of claim 1, wherein the CuO powder and the PbO powder are included in amounts of 10 mol % or less.

3. The ceramic composition claim 1, further comprising a ZnO powder in an amount of 10 mol % or less.

4. A method for manufacturing a ceramic composition for a piezoelectric actuator, the method comprising:
manufacturing a piezoelectric ceramic powder expressed by a Chemical Formula: (1-x)Pb(Zr_{(1-y)}Ti_{y})O₃-xPb(Ni_{1/3}Nb_{2/3})O₃ by mixing and calcinating a powder material, wherein x is 0.25 to 0.4 and y is 0.4 to 0.7; and
mixing the piezoelectric ceramic powder with a CuO powder and a PbO powder.

5. The method claim 4, wherein the powder material is PbO, ZrO, TiO₂, NiO, and Nb₂O₅.

6. The method of claim 4, wherein the CuO powder and the PbO powder are mixed in amounts of 10 mol % or less.

7. The method of claim 4, wherein the mixing further mixes ZnO at 10 mol % or less.

8. A piezoelectric actuator comprising:
at least one piezoelectric layer comprising a ceramic composition comprising a piezoelectric ceramic powder expressed by a Chemical Formula: (1-x)Pb(Zr_{(1-y)}Ti_{y})O₃-xPb(Ni_{1/3}Nb_{2/3})O₃, wherein x is 0.25 to 0.4 and y is 0.4 to 0.7, and a CuO powder and a PbO powder forming a liquid-phase compound at a sintering temperature or less of the piezoelectric ceramic powder; and
an electrode layer formed on at least one of the top surface and the bottom surface of the piezoelectric layer.

9. The piezoelectric actuator of claim 8, wherein the piezoelectric layer further includes ZnO in an amount of 10 mol % or less.

10. The piezoelectric actuator of claim 8, wherein the electrode layer includes at least one selected from the group consisting of silver, copper, and aluminum.

11. A method for manufacturing a piezoelectric actuator, the method comprising:
manufacturing a piezoelectric ceramic powder expressed by a Chemical Formula: (1-x)Pb(Zr_{(1-y)}Ti_{y})O₃-xPb(Ni_{1/3}Nb_{2/3})O₃ by mixing and calcinating a powder material, wherein x is 0.25 to 0.4 and y is 0.4 to 0.7; and
manufacturing a ceramic composition by mixing the piezoelectric ceramic powder with a CuO powder and a PbO powder forming a liquid-phase compound at a sintering temperature or less of the piezoelectric ceramic powder;
forming a piezoelectric layer using the ceramic composition;
forming a laminate by forming an electrode layer on at least one of the top surface and the bottom surface of the piezoelectric layer; and
firing the laminate at 950° C. or less.

12. The method of claim 11, wherein the powder material is PbO, ZrO, TiO₂, NiO, and Nb₂O₅.

13. The method of claim 11, wherein the CuO powder and the PbO powder are mixed in amounts of 10 mol % or less.

14. The method of claim 11, wherein the manufacturing of the ceramic composition further mixes a ZnO powder in an amount of 10 mol % or less.

15. The method of claim 11, wherein the electrode layer includes at least one selected from a group consisting of silver, copper, and aluminum.
